(19) United States
(12) Patent Application Publication
(10) Pub. No.: US 2025/0113554 A1
(43) Pub. Date: Apr. 3, 2025

(54) SEMICONDUCTOR DEVICE

(71) Applicant: Sony Semiconductor Solutions Corporation, Kanagawa (JP)

(72) Inventor: Kenichi Ookubo, Kanagawa (JP)

(21) Appl. No.: 18/730,425

(22) PCT Filed: Jan. 17, 2023
(86) PCT No.: PCT/JP23/01188

§ 371 Date: Jul. 19, 2024

(30) Foreign Application Priority Data
Mar. 10, 2022 (JP) 2022-036968

(51) Int. Cl. H10D 62/10; H10D 62/00; H10F 39/00

(52) U.S. Cl. CPC H10D 62/102; H10D 62/052; H10F 39/8037

(57) ABSTRACT

Semiconductor devices configured to achieve a high withstand voltage are disclosed. In one example, a semiconductor device includes an SJ layer extending in a first direction and configured by alternately arraying semiconductor regions of a first conductivity type and semiconductor regions of a second conductivity type in a second direction orthogonal to the first direction. A first drain layer of the first conductivity type is electrically connected to the SJ layer on a first end side in the first direction, a channel layer of the second conductivity type is provided on the SJ layer on a second end side in the first direction, a first source layer of the first conductivity type is provided on the channel layer, and a first gate electrode is provided on a side of the channel layer and the first source layer in the first direction with a first insulating layer interposed therebetween.

### TECHNICAL FIELD

The present disclosure relates to a semiconductor device.

### BACKGROUND ART

In recent years, in order to cope with more various applications, there is an increasing demand for a high voltage transistor capable of handling a large current.

For example, Patent Document 1 below discloses a vertical transistor including a drift layer having a repeating structure (so-called super junction structure) of a P-type region and an N-type region. In the vertical transistor disclosed in Patent Document 1, since a thick depletion layer is formed in the drift layer, a withstand voltage can be further enhanced.

### CITATION LIST

### Patent Document

PATENT DOCUMENT 1 Japanese Patent Application Laid-Open No. 2012-160753

### SUMMARY OF THE INVENTION

### Problems to be Solved by the Invention

However, in the vertical transistor disclosed in Patent Document 1 described above, the film thickness of the drift layer increases as the withstand voltage increases, and thus the height increases. Therefore, the vertical transistor disclosed in Patent Document 1 is not suitable for miniaturization.

Therefore, the present disclosure proposes a novel and improved semiconductor device capable of achieving a high withstand voltage and having a structure suitable for miniaturization.

### Solutions to Problems

According to the present disclosure, there is provided a semiconductor device including: an SJ layer extending in a first direction in a plane and configured by alternately arraying a plurality of semiconductor regions of a first conductivity type and a plurality of semiconductor regions of a second conductivity type in a second direction orthogonal to the first direction; a first drain layer of the first conductivity type electrically connected to the SJ layer on one end side in the first direction; a channel layer of the second conductivity type provided on the SJ layer on the other end side in the first direction; a first source layer of the first conductivity type provided on the channel layer; and a first gate electrode provided on a side of the channel layer and the first source layer in the first direction with a first insulating layer interposed therebetween.

### BRIEF DESCRIPTION OF DRAWINGS

FIG. 1 is a transparent perspective view illustrating a configuration of a semiconductor device according to an embodiment of the present disclosure.

FIG. 2 is a cross-sectional view illustrating a configuration of a semiconductor device according to the embodiment.

FIG. 3A is a perspective view illustrating a step of manufacturing the semiconductor device according to the embodiment.

FIG. 3B is a perspective view illustrating a step of manufacturing the semiconductor device according to the embodiment.

FIG. 3C is a perspective view illustrating a step of manufacturing the semiconductor device according to the embodiment.

FIG. 3D is a perspective view illustrating a step of manufacturing the semiconductor device according to the embodiment.

FIG. 3E is a perspective view illustrating a step of manufacturing the semiconductor device according to the embodiment.

FIG. 3F is a perspective view illustrating a step of manufacturing the semiconductor device according to the embodiment.

FIG. 3G is a perspective view illustrating a step of manufacturing the semiconductor device according to the embodiment.

FIG. 3H is a perspective view illustrating a step of manufacturing the semiconductor device according to the embodiment.

FIG. 3I is a perspective view illustrating one step of manufacturing the semiconductor device according to the embodiment.

FIG. 3J is a perspective view illustrating a step of manufacturing the semiconductor device according to the embodiment,

FIG. 3K is a perspective view illustrating a step of manufacturing the semiconductor device according to the embodiment.

FIG. 4 is a top view illustrating a configuration of a semiconductor device according to a first modification.

FIG. 5 is a top view illustrating a configuration of a semiconductor device according to a second modification.

FIG. 6 is a transparent perspective view illustrating a configuration of a semiconductor device according to a third modification.

FIG. 7 is a top view illustrating a configuration of a semiconductor device according to a fourth modification.

FIG. 8 is a top view illustrating a configuration of a semiconductor device according to a fifth modification.

FIG. 9 is a transparent perspective view illustrating a configuration of a semiconductor device according to a sixth modification.

FIG. 10 is a transparent perspective view illustrating a configuration of a semiconductor device according to a seventh modification.

FIG. 11 is a cross-sectional view illustrating a configuration of a stacked semiconductor device to which the semiconductor device according to the embodiment is applied.

### MODE FOR CARRYING OUT THE INVENTION

Hereinafter, preferred embodiments of the present disclosure will be described in detail with reference to the accompanying drawings. Note that, in the present description and the drawings, constituent elements having substantially the same functional configurations will be given the same reference signs, and redundant explanations will be omitted.

Note that the description will be given in the following order.
1. Configuration example
2. Production method
3. Modifications
4. Application example

### <1. Configuration Example>

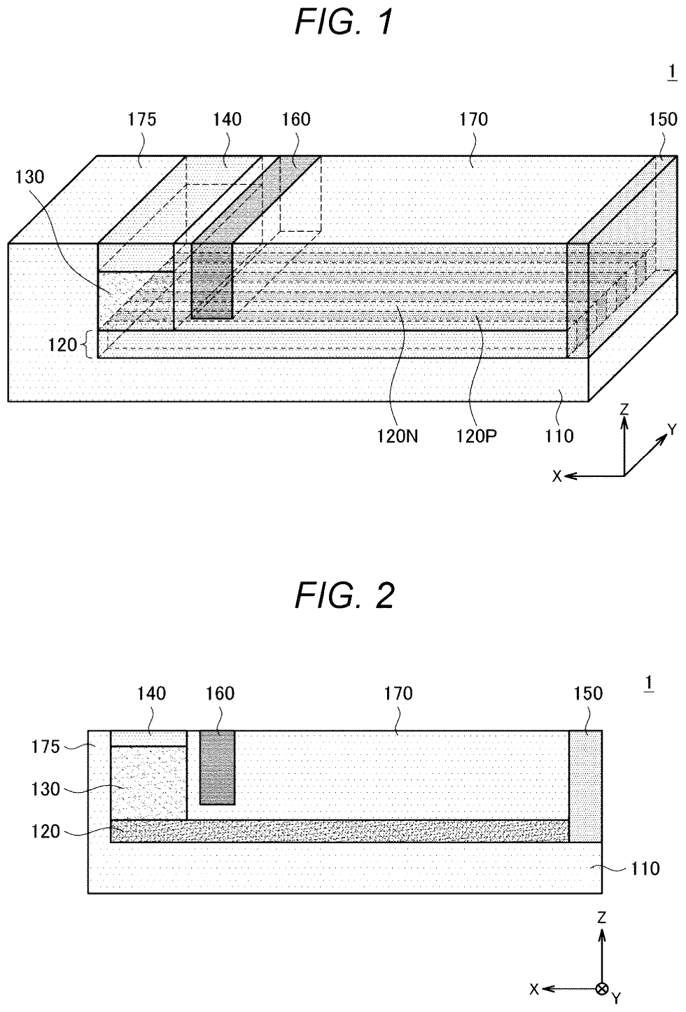

First, a configuration of a semiconductor device according to an embodiment of the present disclosure will be described with reference to FIGS. 1 and 2. FIG. 1 is a transparent perspective view illustrating a configuration of a semiconductor device 1 according to the present embodiment. In FIG. 1, a horizontal direction facing the drawing is defined as an X-axis direction, a vertical direction facing the drawing is defined as a Z-axis direction, and a front-back direction with respect to a paper surface of the drawing is defined as a Y-axis direction. FIG. 2 is a cross-sectional view illustrating a configuration of the semiconductor device 1 according to the present embodiment. FIG. 2 illustrates a cross section of the semiconductor device 1 illustrated in FIG. 1 taken along a ZX plane.

As illustrated in FIGS. 1 and 2, the semiconductor device 1 according to the present embodiment includes a base insulating layer 110, a super junction (SJ) layer 120, a channel layer 130, a source layer 140, a drain layer 150, a gate electrode 160, an insulating layer 170, and an element isolation layer 175.

Hereinafter, a first conductivity type represents either the P type or the N type, and a second conductivity type represents the other of the P type or the N type different from the first conductivity type. That is, in a case where the first conductivity type is the N-type, the second conductivity type is the P-type. Furthermore, in a case where the first conductivity type is the P-type, the second conductivity type is the N-type.

The base insulating layer 110 includes an inorganic insulating material, supports the SJ layer 120 and the drain layer 150, and insulates the SJ layer 120 and the drain layer 150 from the configuration below in the Z-axis direction (for example, a semiconductor substrate that supports the semiconductor device 1, and so on). The semiconductor device 1 can enhance the withstand voltage in the Z-axis direction by providing the insulating base insulating layer 110 under the SJ layer 120. For example, the base insulating layer 110 may include silicon oxide (SiOₓ), silicon nitride (SiNₓ), silicon oxynitride (SiON), or the like.

The SJ layer 120 includes a semiconductor region 120N of the first conductivity type (for example, N-type) and a semiconductor region 120P of the second conductivity type (for example, P-type), and is provided on the base insulating layer 110. Specifically, the SJ layer 120 may be provided as a Si layer in which the semiconductor region 120N and the semiconductor region 120P extending in the X-axis direction (that is, a first direction) are alternately and repeatedly arrayed in the Y-axis direction (that is, a second direction) orthogonal to the X-axis direction.

In the SJ layer 120, the semiconductor region 120N of the first conductivity type functions as a conduction path. Specifically, when the channel layer 130 is turned on by voltage application to the gate electrode 160, a current flows from the source layer 140 to the drain layer 150 through the channel layer 130 and the semiconductor region 120N of the SJ layer 120.

As described above, the SJ layer 120 is provided in a super junction structure in which the semiconductor region 120N of the first conductivity type and the semiconductor region 120P of the second conductivity type are alternately arranged in the Y-axis direction. In the super junction structure, when a voltage is applied between the drain layer 150 and the source layer 140, for example, a depletion layer extends from the semiconductor region 120P of the second conductivity type to the semiconductor region 120N of the first conductivity type. As a result, since the semiconductor region 120N of the first conductivity type has substantially uniform electric field strength, a yield phenomenon hardly occurs, and a thick depletion layer is formed, so that the SJ layer 120 can have extremely high withstand voltage.

Further, in the SJ layer 120, since a spread width of the depletion layer in the semiconductor region 120N of the first conductivity type is small, the depletion layer can be appropriately formed in the semiconductor region 120N of the first conductivity type even in a case where the concentration of the conductivity type impurity is higher. Therefore, the SJ layer 120 can further reduce an electrical resistance of the semiconductor region 120N by further increasing the concentration of the conductivity type impurity included in the semiconductor region 120N of the first conductivity type. According to this, the semiconductor device 1 can further reduce the on-resistance.

The drain layer 150 includes a semiconductor of the first conductivity type, and is provided in contact with one end side of the SJ layer 120 in the X-axis direction to extend in the Z-axis direction. Specifically, the drain layer 150 may be provided on the base insulating layer 110 in electrical contact with a side surface of the SJ layer 120 on one end side (for example, the right side in FIGS. 1 and 2) in the X-axis direction. According to this, the drain layer 150 can take out a drain current in the Z-axis direction on the opposite side of the base insulating layer 110 from the side surfaces of the plurality of semiconductor regions 120N of the first conductivity type. For example, the drain layer 150 may be provided as an N-type Si layer.

The channel layer 130 includes a semiconductor of the second conductivity type, and is provided on the SJ layer 120 on the other end side (for example, the left side in FIGS. 1 and 2) opposite to the one end side on which the drain layer 150 in the X-axis direction is provided. Specifically, the channel layer 130 may be provided on the SJ layer 120 on the other end side in the X-axis direction so as to spread over the plurality of semiconductor regions 120N of the first conductivity type. For example, the channel layer 130 may be provided as a P-type Si layer.

The source layer 140 includes a semiconductor of the first conductivity type, and is provided on the channel layer 130. Specifically, the source layer 140 may be provided on the channel layer 130 so as to sandwich the channel layer 130 in the Z-axis direction with the SJ layer 120. For example, the source layer 140 may be provided as an N-type Si layer.

The insulating layer 170 includes an inorganic insulating material, and is provided on the SJ layer 120 so as to fill a space between the drain layer 150 and a laminated body of the channel layer 130 and the source layer 140. The insulating layer 170 may include, for example, silicon oxide (SiOₓ), silicon nitride (SiNₓ), silicon oxynitride (SiON), or the like.

The gate electrode 160 includes a conductive material, and is provided on the side of the laminated body of the channel layer 130 and the source layer 140 with the insulating layer 170 interposed therebetween. Specifically, the gate electrode 160 is provided so as to be buried in the insulating layer 170 on the other end side in the X-axis direction while being separated from the channel layer 130, the source layer 140, and the SJ layer 120. For example, the gate electrode 160 may include polysilicon (poly-Si).

As a result, in the semiconductor device 1, since a metal-insulator-semiconductor (MIS) gate structure can be formed by the gate electrode 160, the insulating layer 170, and the channel layer 130, conduction of the channel layer 130 can be controlled by applying a voltage to the gate electrode 160. That is, the semiconductor device 1 is a field effect transistor having a vertical gate structure in which a conduction path electrically connecting the source layer 140 and the drain layer 150 is formed in the channel layer 130 in the Z-axis direction.

The element isolation layer 175 includes an inorganic insulating material, and is provided to extend in the Z-axis direction on the base insulating layer 110, thereby electrically insulating the semiconductor device 1 from other elements and the like. For example, the element isolation layer 175 may be provided to extend in the Z-axis direction on the side opposite to the drain layer 150 side of the laminated body of the channel layer 130 and the source layer 140. For example, the element isolation layer 175 may include silicon oxide (SiOₓ), silicon nitride (SiNₓ), silicon oxynitride (SiON), or the like.

In the semiconductor device 1 according to the present embodiment, the SJ layer 120 having a super junction structure is provided between the channel layer 130 and the drain layer 150. In the SJ layer 120, a thick depletion layer can be formed between the channel layer 130 and the drain layer 150 by applying a voltage between the drain layer 150 and the source layer 140, so that the withstand voltage of the semiconductor device 1 can be further enhanced. Further, in the SJ layer 120, since the depletion layer expands in the Y-axis direction, the depletion layer can be sufficiently formed even in a case where the concentration of the conductivity type impurity in the SJ layer 120 is high. Therefore, since the semiconductor device 1 can reduce the electrical resistance of the SJ layer 120 by increasing the concentration of the conductivity type impurity of the SJ layer 120, the on-resistance can be further reduced.

Furthermore, in the semiconductor device 1 according to the present embodiment, the SJ layer 120 is provided to extend not in the thickness direction (that is, in the Z-axis direction,) but in an XY in-plane direction. Therefore, the semiconductor device 1 can further reduce the thickness of the entire device (that is, height is reduced.) as compared with a case where the SJ layer 120 is provided to extend in the Z-axis direction.

Furthermore, in the semiconductor device 1 according to the present embodiment, the source layer 140, the gate electrode 160, and the drain layer 150 are provided so as to be exposed on the upper surface on the side opposite to the surface on the base insulating layer 110 side. According to this, in the semiconductor device 1, since the electrical connection with the source layer 140, the drain layer 150, and the gate electrode 160 can be formed from the same surface side, the wiring to these can be more easily formed.

### <2. Manufacturing Method>

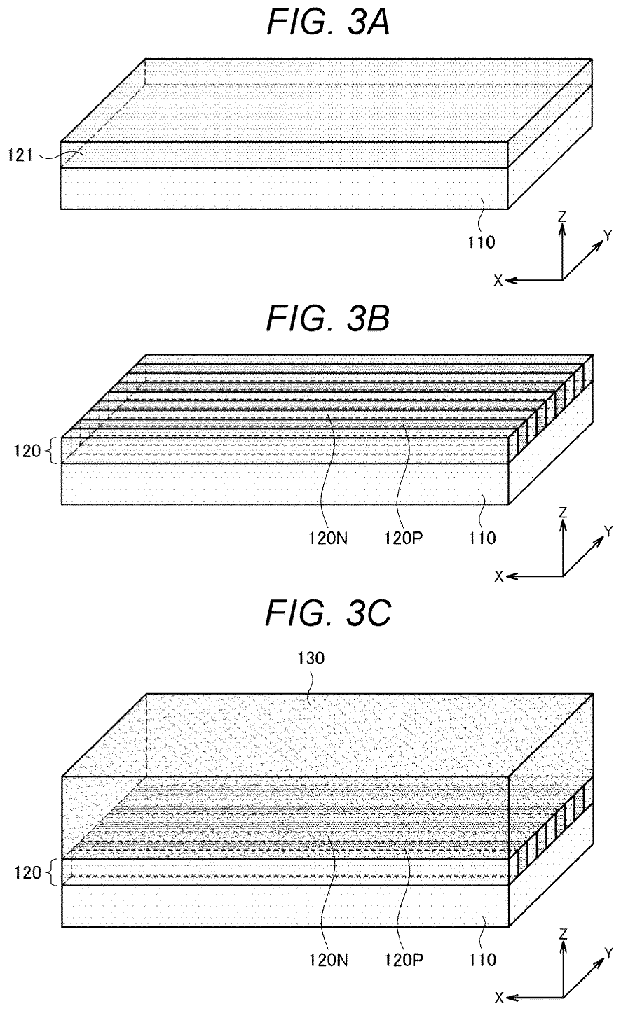

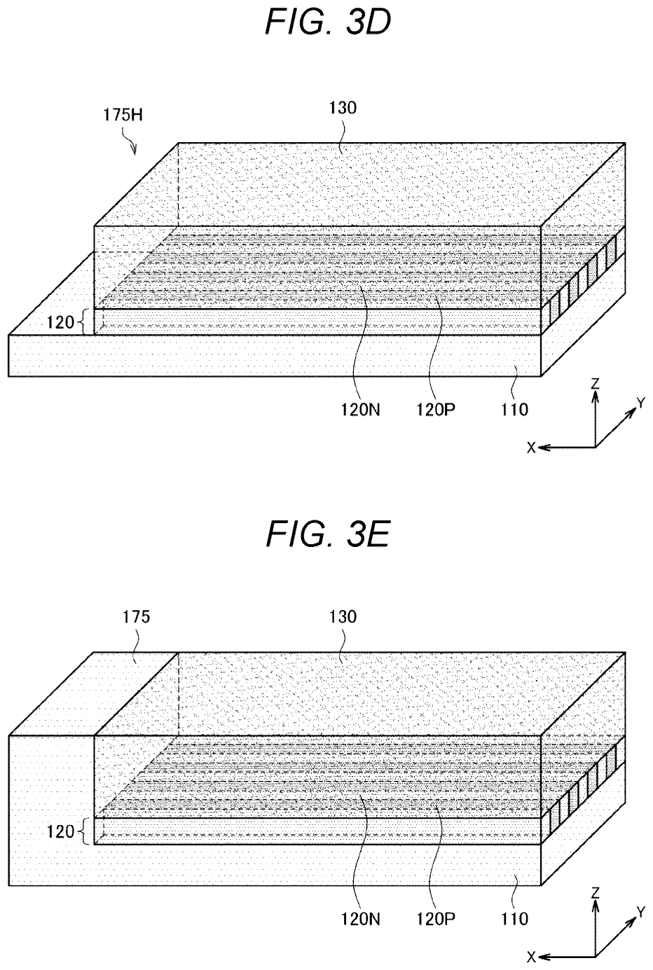

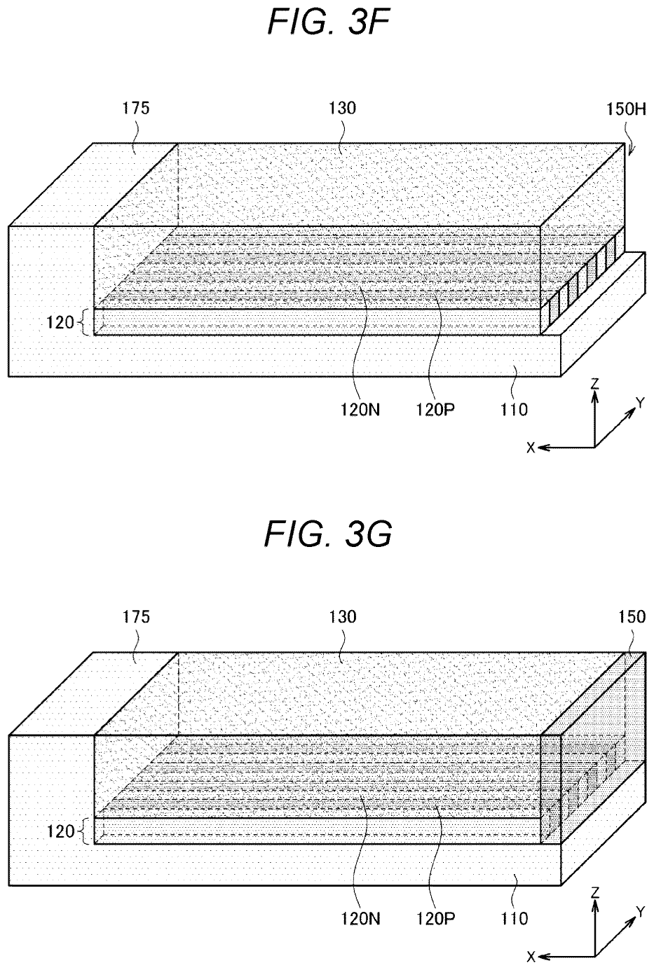

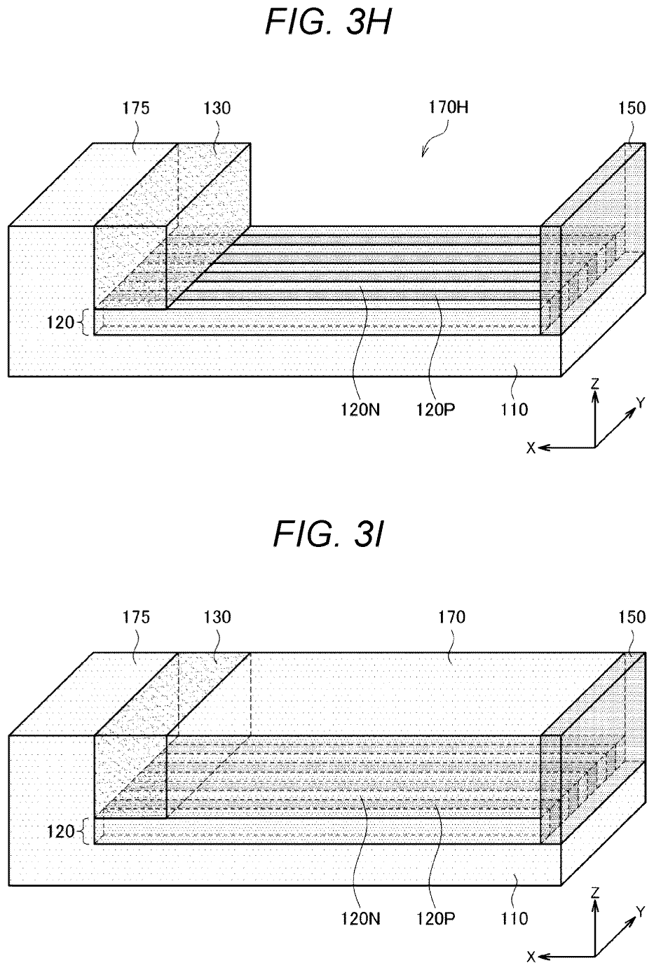

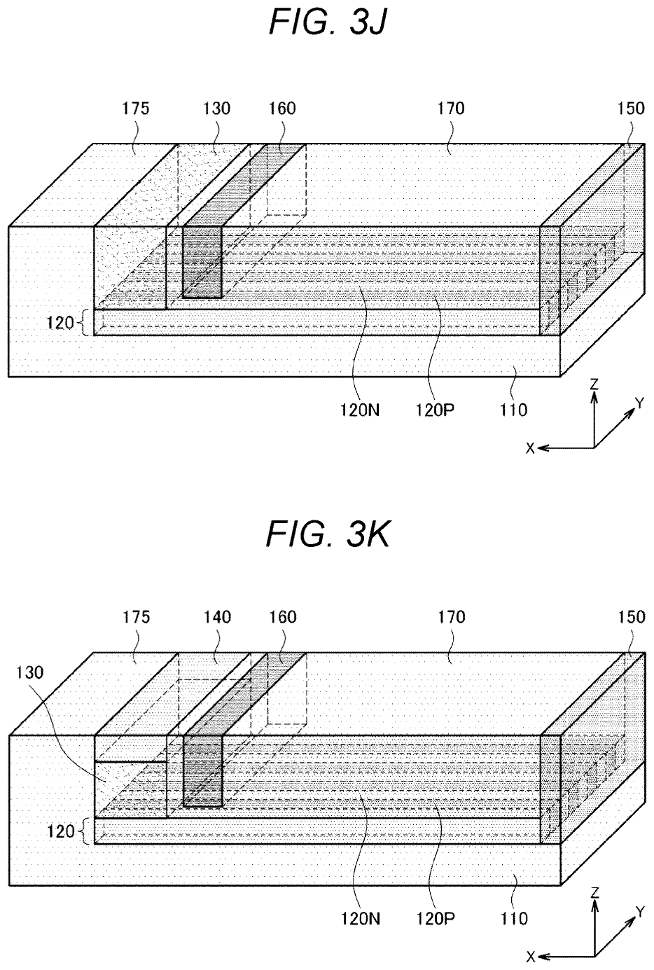

Next, an example of a method of manufacturing the semiconductor device 1 according to the present embodiment will be described with reference to FIGS. 3A to 3K. FIGS. 3A to 3K are perspective views illustrating one step of manufacturing the semiconductor device 1 according to the present embodiment.

First, as illustrated in FIG. 3A, an SJ precursor layer 121 of the first conductivity type is formed on the base insulating layer 110 extending in the X-axis direction. For example, the SJ precursor layer 121 is formed by epitaxially growing Si of the first conductivity type (for example, N-type) on the base insulating layer 110 including SiO₂.

Next, as shown in FIG. 3B, second conductivity type impurities are introduced into the SJ precursor layer 121 of the first conductivity type to form the SJ layer 120. For example, second conductivity type impurities (for example, boron, aluminum, or the like) are ion-implanted into the SJ precursor layer 121 of the first conductivity type using a resist extending in the X-axis direction as a mask, the resist being patterned in a stripe shape at predetermined intervals in the Y-axis direction. As a result, the SJ layer 120 in which the semiconductor regions 120N of the first conductivity type (for example, N-type) and the semiconductor regions 120P of the second conductivity type (for example, P-type) extending in the X-axis direction are alternately arrayed in the Y-axis direction is formed.

Subsequently, as illustrated in FIG. 3C, the channel layer 130 of the second conductivity type is formed on the SJ layer 120. For example, the channel layer 130 is formed by epitaxially growing second conductivity type (for example, P-type) Si on the SJ layer 120.

Next, as illustrated in FIG. 3D, the channel layer 130 and the SJ layer 120 on the other end side (left side as viewed from the front in the drawing) in the X-axis direction provided on the base insulating layer 110 are removed by etching, whereby an opening 175H is formed.

Thereafter, as illustrated in FIG. 3E, the opening 175H is filled with an inorganic insulating material, whereby the element isolation layer 175 is formed. For example, the element isolation layer 175 is formed by depositing SiO₂ using chemical vapor deposition (CVD) or the like so as to fill the opening 175H.

Furthermore, as illustrated in FIG. 3F, the channel layer 130 and the SJ layer 120 on one end side (right side as viewed from the front in the drawing) opposite to the other end side in the X-axis direction provided on the base insulating layer 110 are removed by etching, whereby the opening 150H is formed.

Thereafter, as illustrated in FIG. 3G, the drain layer 150 is formed so as to fill the opening 150H. For example, the drain layer 150 is formed by epitaxially growing Si of the first conductivity type (for example, N-type) on the base insulating layer 110 so as to fill the opening 150H.

Next, as illustrated in FIG. 3H, the channel layer 130 on the SJ layer 120 is removed by etching while leaving a part of the channel layer 130 on the other end side in the X-axis direction, whereby the opening 170H is formed.

Subsequently, as illustrated in FIG. 3I, the insulating layer 170 is formed so as to fill the opening 170H. For example, the insulating layer 170 is formed by depositing SiO₂ using CVD or the like so as to fill the opening 170H.

Thereafter, as illustrated in FIG. 3J, the gate electrode 160 embedded in the insulating layer 170 is formed on the side of the channel layer 130. For example, first, the insulating layer 170 on the side of the channel layer 130 and in a part of a region separated from the channel layer 130 is removed by etching to form an opening. Next, after poly-Si is deposited so as to embed the formed opening, the surface of the insulating layer 170 is planarized by chemical mechanical polishing (CMP), whereby the gate electrode 160 embedded in the insulating layer 170 is formed.

Further, as illustrated in FIG. 3K, the source layer 140 is formed by introducing the first conductivity type impurity into an upper portion of the channel layer 130. For example, the source layer 140 is formed on the upper portion of the channel layer 130 by ion-implanting first conductivity type impurities (for example, phosphorus or arsenic) into the channel layer 130.

Through the above steps, the semiconductor device 1 according to the present embodiment is manufactured. In the semiconductor device 1, the SJ layer 120 is provided to extend in the XY in-plane direction orthogonal to the thickness direction (that is, the Z-axis direction) of the semiconductor device 1. Therefore, according to the present embodiment, the semiconductor device 1 having a low on-resistance and a high withstand voltage can be manufactured with a smaller height.

### <3. Modifications>

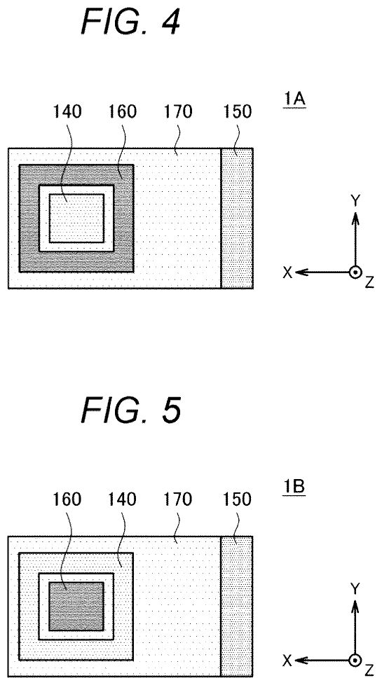

Next, first to seventh modifications of the semiconductor device 1 according to the present embodiment will be described with reference to FIGS. 4 to 10.

### (First Modification)

FIG. 4 is a top view illustrating a configuration of a semiconductor device 1A according to a first modification. FIG. 4 illustrates a configuration in which an upper surface of the semiconductor device 1A is viewed in plan view from the Z-axis direction.

As illustrated in FIG. 4, in the semiconductor device 1A, the gate electrode 160 may be provided so as to surround an entire lateral periphery of the laminated body of the channel layer 130 and the source layer 140. Specifically, the gate electrode 160 may be provided on the SJ layer 120 so as to surround an entire periphery of the laminated body of the channel layer 130 and the source layer 140 provided in an island shape at the other end side (left side facing the drawing) in the X-axis direction of the SJ layer 120 and at the center in the Y-axis direction.

According to this, in the semiconductor device 1A according to the first modification, since four side surfaces of the channel layer 130 can be used as a gate, an effective gate length can be further increased. Therefore, the semiconductor device 1A according to the first modification can further suppress a leakage current in an off state by suppressing the short channel effect.

### (Second Modification)

FIG. 5 is a top view illustrating a configuration of a semiconductor device 1B according to a second modification. FIG. 5 illustrates a configuration in which an upper surface of the semiconductor device 1B is viewed in plan view from the Z-axis direction.

Since the laminated body of the channel layer 130 and the source layer 140 and the gate electrode 160 only need to face each other with the insulating layer 170 interposed therebetween, a positional relationship between the laminated body of the channel layer 130 and the source layer 140 and the gate electrode 160 may be reversed. That is, as illustrated in FIG. 5, in the semiconductor device 1B, the laminated body of the channel layer 130 and the source layer 140 may be provided so as to surround the entire periphery of the gate electrode 160.

Specifically, the laminated body of the channel layer 130 and the source layer 140 may be provided on the SJ layer 120 so as to surround the entire periphery of the gate electrode 160 provided on the other end side (left side as viewed from the front in the figure) in the X-axis direction of the SJ layer 120 and in an island shape at the center in the Y-axis direction. Even in such a case, in the semiconductor device 1B, the MIS gate structure can be formed by the gate electrode 160 and the channel layer 130 facing each other with the insulating layer 170 interposed therebetween.

According to this, in the semiconductor device 1B according to the second modification, the gate can be formed on the four side surfaces of the gate electrode 160 by the channel layer 130 surrounding the entire periphery of the gate electrode 160. Therefore, the semiconductor device 1B according to the second modification can suppress the short channel effect by making the effective gate length longer.

### (Third Modification)

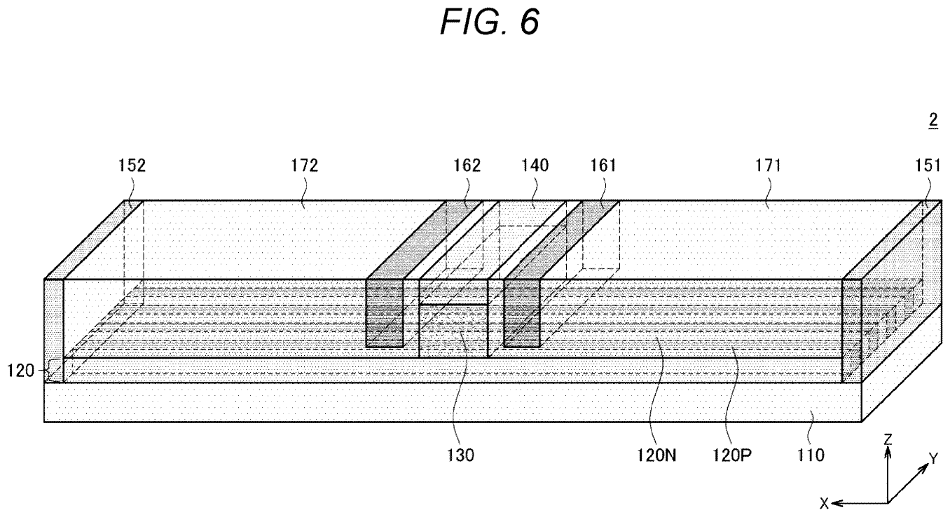

FIG. 6 is a transparent perspective view illustrating a configuration of a semiconductor device 2 according to a third modification. In FIG. 6, a horizontal direction facing the drawing is defined as an X-axis direction, a vertical direction facing the drawing is defined as a Z-axis direction, and a front-back direction with respect to a paper surface of the drawing is defined as a Y-axis direction.

As illustrated in FIG. 6, the semiconductor device 2 includes a base insulating layer 110, an SJ layer 120, a channel layer 130, a source layer 140, a first drain layer 151, a first gate electrode 161, a first insulating layer 171, a second drain layer 152, a second gate electrode 162, and a second insulating layer 172.

In the semiconductor device 2, the base insulating layer 110 and the SJ layer 120 are provided to extend in the X-axis direction beyond a laminated body of the channel layer 130 and the source layer 140. In the semiconductor device 2, the first gate electrode 161 and the first drain layer 151 are provided on one end side (right side as viewed from the front in the drawing) in the X-axis direction of the laminated body of the channel layer 130 and the source layer 140, and the second gate electrode 162 and the second drain layer 152 are provided on the other end side (left side as viewed from the front in the drawing).

Specifically, the laminated body of the channel layer 130 and the source layer 140 is provided at the center in the X-axis direction of the SJ layer 120 provided to extend in the X-axis direction. Further, the first drain layer 151 of the first conductivity type is provided to extend in the Z axis direction on one end side in the X axis direction of the SJ layer 120, and the second drain layer 152 of the first conductivity type is provided to extend in the Z axis direction on the other end side in the X axis direction of the SJ layer 120.

Furthermore, the first insulating layer 171 is provided on the SJ layer 120 so as to embed between the laminated body of the channel layer 130 and the source layer 140 and the first drain layer 151, and the first gate electrode 161 is embedded in the channel layer 130 side of the first insulating layer 171. As a result, a MIS gate structure is formed by the first gate electrode 161 and the channel layer 130 facing each other with the first insulating layer 171 interposed therebetween.

Similarly, the second insulating layer 172 is provided on the SJ layer 120 so as to embed between the laminated body of the channel layer 130 and the source layer 140 and the second drain layer 152, and the second gate electrode 162 is embedded in the channel layer 130 side of the second insulating layer 172. As a result, a MIS gate structure is formed by the second gate electrode 162 and the channel layer 130 facing each other with the second insulating layer 172 interposed therebetween.

According to this, in the semiconductor device 2 according to the third modification, the vertical transistors can be formed on both sides in the X-axis direction with the laminated body of the channel layer 130 and the source layer 140 interposed therebetween.

### (Fourth Modification)

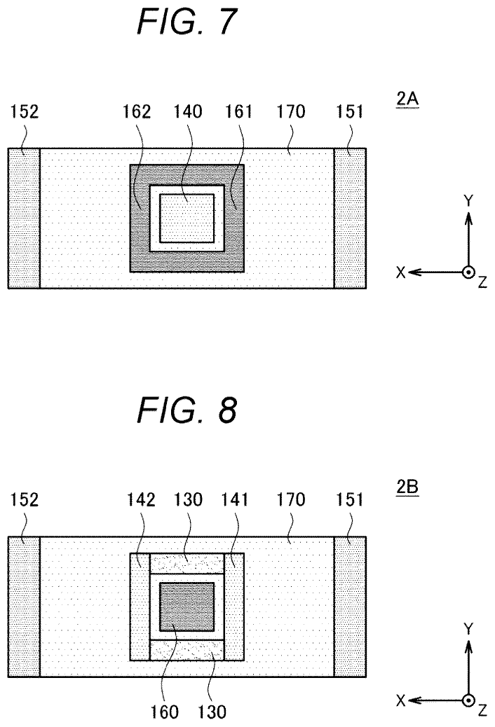

FIG. 7 is a top view illustrating a configuration of a semiconductor device 2A according to a fourth modification. FIG. 7 illustrates a configuration in which an upper surface of the semiconductor device 1A is viewed in plan view from the Z-axis direction.

As illustrated in FIG. 7, in the semiconductor device 2A, the first gate electrode 161 and the second gate electrode 162 may be continuously provided so as to surround the entire periphery of the laminated body of the channel layer 130 and the source layer 140. Specifically, the first gate electrode 161 and the second gate electrode 162 may be continuously provided on the SJ layer 120 so as to surround the entire periphery of the laminated body of the channel layer 130 and the source layer 140 provided in an island shape at the center in the X-axis direction and the center in the Y-axis direction of the SJ layer 120.

According to this, in the semiconductor device 2A according to the fourth modification, since the plurality of side surfaces of the channel layer 130 can be used as gates, an effective gate length can be further increased. Therefore, the semiconductor device 2A according to the fourth modification can further suppress the leakage current in the off state by suppressing the short channel effect.

### (Fifth Modification)

FIG. 8 is a top view illustrating a configuration of a semiconductor device 2B according to a fifth modification. FIG. 8 illustrates a configuration in which the upper surface of the semiconductor device 2B is viewed in plan view from the Z-axis direction.

Since the laminated body of the channel layer 130 and the source layer 140 and the gate electrode 160 only need to face each other with the insulating layer 170 interposed therebetween, a positional relationship between the laminated body of the channel layer 130 and the source layer 140 and the gate electrode 160 may be reversed. That is, as illustrated in FIG. 8, in the semiconductor device 2B, the channel layer 130 may be provided so as to surround the entire circumference of the gate electrode 160 that realizes the functions of the first gate electrode 161 and the second gate electrode 162.

Specifically, the channel layer 130 is provided on the SJ layer 120 so as to surround the entire circumference of the gate electrode 160 provided in an island shape at the center in the X-axis direction and the center in the Y-axis direction of the SJ layer 120. Also, the first source layer 141 is provided to extend in the Y-axis direction on the channel layer 130 provided between the gate electrode 160 and the first drain layer 151. The second source layer 142 is provided to extend in the Y-axis direction on the channel layer 130 provided between the gate electrode 160 and the second drain layer 152. Even in such a case, the semiconductor device 2B can form the MIS gate structure by the gate electrode 160 and the channel layer 130 facing each other with the insulating layer 170 interposed therebetween.

According to this, in the semiconductor device 2B according to the fifth modification, the gate can be formed on the four side surfaces of the gate electrode 160 by the channel layer 130 surrounding the entire periphery of the gate electrode 160. Therefore, the semiconductor device 2B according to the fifth modification can suppress the short channel effect by making the effective gate length longer.

### (Sixth Modification)

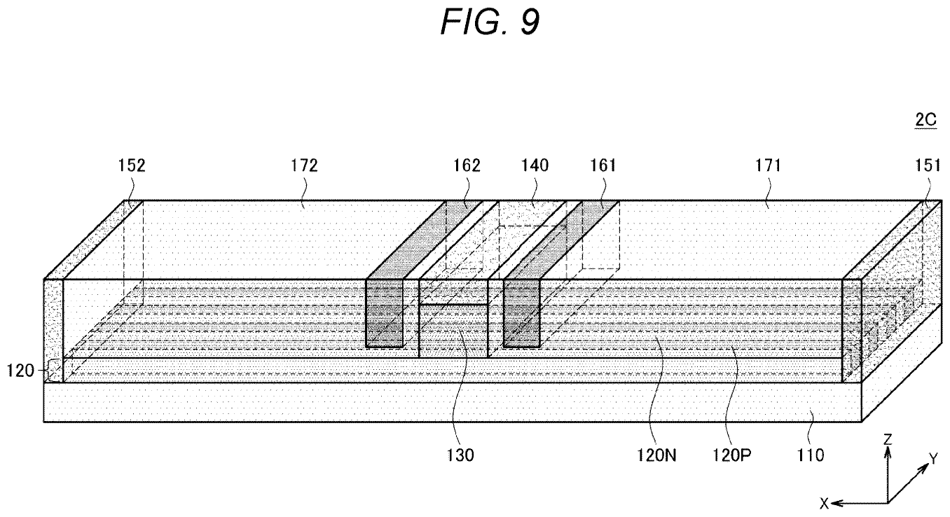

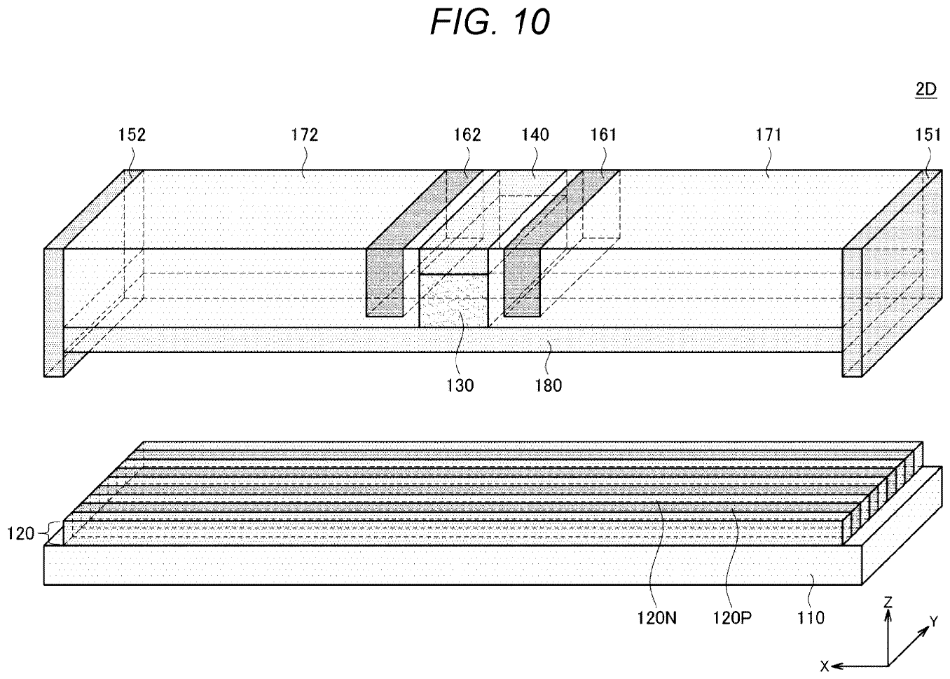

FIG. 9 is a transparent perspective view illustrating a configuration of a semiconductor device 2C according to a sixth modification. In FIG. 9, a horizontal direction facing the drawing is defined as an X-axis direction, a vertical direction facing the drawing is defined as a Z-axis direction, and a front-back direction with respect to a paper surface of the drawing is defined as a Y-axis direction.

As illustrated in FIG. 9, in the semiconductor device 20, the polarity of the conductivity type of the source layer 140, the channel layer 130, the first drain layer 151, and the second drain layer 152 may be opposite to that of the semiconductor device 2 illustrated in FIG. 6. Specifically, in the semiconductor device 2C, the source layer 140 may be provided with the second conductivity type (for example, P type), the channel layer 130 may be provided with the first conductivity type (for example, N type), and the first drain layer 151 and the second drain layer 152 may be provided with the second conductivity type (for example, P type).

According to this, the semiconductor device 20 can function as a P-type channel transistor while the semiconductor device 2 illustrated in FIG. 6 functions as an N-type channel transistor. Even in such a case, the semiconductor device 20 can be formed with a structure in which the height of the vertical transistor having reduced on-resistance and enhanced withstand voltage is further reduced.

### (Seventh Modification)

FIG. 10 is a transparent perspective view illustrating a configuration of a semiconductor device 2D according to a seventh modification. In FIG. 10, a horizontal direction facing the drawing is defined as an X-axis direction, a vertical direction facing the drawing is defined as a Z-axis direction, and a front-back direction with respect to a paper surface of the drawing is defined as a Y-axis direction.

As illustrated in FIG. 10, in the semiconductor device 2D, the first insulating layer 171, the second insulating layer 172, and the intermediate layer 180 of the first conductivity type (for example, N type) are provided between the channel layer 130 and the SJ layer 120. Since the intermediate layer 180 is provided to extend in the X-axis direction on the SJ layer 120, electric resistance between the channel layer 130, and the first drain layer 151 and the second drain layer 152 can be reduced. According to this, the semiconductor device 2D can further reduce the on-resistance.

### <4. Application Example>

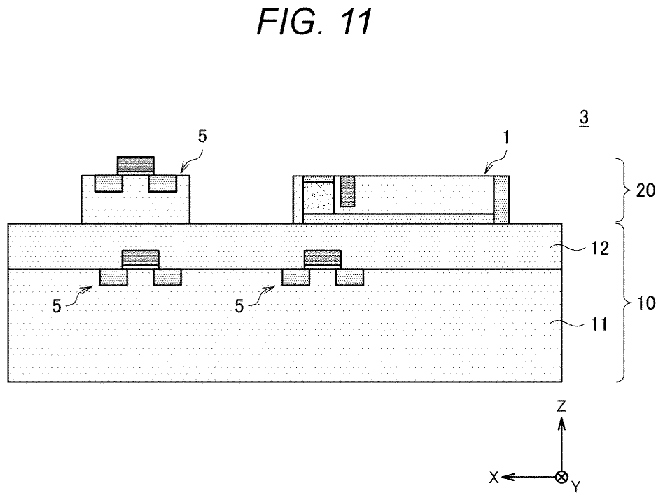

Furthermore, an application example of the semiconductor device 1 according to the present embodiment will be described with reference to FIG. 11. FIG. 11 is a cross-sectional view illustrating a configuration of a stacked semiconductor device 3 to which the semiconductor device 1 according to the present embodiment is applied. FIG. 11 illustrates a cross section of the stacked semiconductor device 3 taken along a ZX plane.

As illustrated in FIG. 11, the stacked semiconductor device 3 has a structure in which a first floor portion 10 and a second floor portion 20 are laminated.

The first floor portion 10 is, for example, a laminated structure of a semiconductor substrate 11 such as a Si substrate and an interlayer insulating layer 12 including an insulating material such as SiO₂. The first floor portion 10 may be provided with, for example, a transistor 5 configuring a logic circuit, a photodiode configuring an image sensor, and the like.

The second floor portion 20 includes, for example, the semiconductor device 1 according to the present embodiment. Since the semiconductor device 1 according to the present embodiment has a small thickness, it is possible to suppress an excessive increase in height of the stacked semiconductor device 3 in which a plurality of substrates and the like are laminated. Therefore, the semiconductor device 1 according to the present embodiment can further downsize the stacked semiconductor device 3.

Note that it goes without saying that the second floor portion 20 may further include a normal planar transistor 5 formed in a semiconductor layer provided on the interlayer insulating layer 12.

The preferred embodiments of the present disclosure have been described above in detail with reference to the accompanying drawings, but the technical scope of the present disclosure is not limited to such examples. It is obvious that those with ordinary skill in the technical field of the present disclosure can conceive various alterations or corrections within the scope of the technical idea recited in the claims, and it is naturally understood that these alterations or corrections also fall within the technical scope of the present disclosure.

Further, the effects disclosed in the present specification are merely illustrative or exemplary, but are not restrictive. That is, the technology according to the present disclosure may achieve other effects obvious to those skilled in the art from the description in the present specification, in addition to or instead of the effects described above.

Note that the following configurations also fall within the technological scope of the present disclosure.

(1)

A semiconductor device including:
an SJ layer extending in a first direction in a plane and configured by alternately arraying a plurality of semiconductor regions of a first conductivity type and a plurality of semiconductor regions of a second conductivity type in a second direction orthogonal to the first direction;
a first drain layer of the first conductivity type electrically connected to the SJ layer on one end side in the first direction;
a channel layer of the second conductivity type provided on the SJ layer on the other end side in the first direction;
a first source layer of the first conductivity type provided on the channel layer; and
a first gate electrode provided on a side of the channel layer and the first source layer in the first direction with a first insulating layer interposed therebetween.

(2)

The semiconductor device according to the above (1), in which the first insulating layer is provided on the SJ layer with the first gate electrode embedded therein.

(3)

The semiconductor device according to the above (1) or (2), in which the first gate electrode is provided between the channel layer and the first source layer, and the first drain layer.

(4)

The semiconductor device according to the above (3), in which
the SJ layer is provided to extend in the first direction beyond the channel layer,
a second drain layer of the first conductivity type is further provided at an end portion of the SJ layer extending beyond the channel layer, and
the semiconductor device further includes a second gate electrode provided through a second insulating layer on a side of the channel layer and the first source layer opposite to a side where the first gate electrode is provided.

(5)

The semiconductor device according to the above (4), in which the first gate electrode and the second gate electrode are continuously provided so as to surround an entire periphery of the channel layer and the first source layer.

(6)

The semiconductor device according to the above (1) or (2), in which the first gate electrode is provided on a side opposite to a side where the first drain layer is provided with respect to the channel layer and the first source layer.

(7)

The semiconductor device according to the above (6), in which the channel layer is provided so as to surround an entire circumference of the first gate electrode.

(8)

The semiconductor device according to the above (7), in which
the SJ layer is provided to extend in the first direction beyond the channel layer,
the semiconductor device further includes a second drain layer of the first conductivity type at an end portion of the SJ layer extending beyond the channel layer, and
a second source layer is provided on the channel layer between the first gate electrode and the second drain layer.

(9)

The semiconductor device according to any one of the above (1) to (8), further including an intermediate layer of the first conductivity type provided between the channel layer and the SJ layer.

(10)

The semiconductor device according to any one of the above (1) to (9), in which a depletion layer is formed in the semiconductor region of the first conductivity type of the SJ layer.

(11)

The semiconductor device according to any one of the above (1) to (10), in which the SJ layer is provided on an interlayer insulating layer including an insulating material.

(12)

The semiconductor device according to the above (11), in which
the interlayer insulating layer is laminated with a semiconductor substrate, and
the SJ layer is provided on a laminated substrate including the interlayer insulating layer and the semiconductor substrate.

(13)

The semiconductor device according to the above (12), in which the laminated substrate is provided with a pixel including a logic circuit or a photodiode.

### REFERENCE SIGNS LIST

1, 1A, 1B, 2, 2A, 2B, 2C, 2D Semiconductor device
110 Base insulating layer
120 SJ layer
130 Channel layer
140 Source layer
141 First source layer
142 Second source layer
150 Drain layer
151 First drain layer
152 Second drain layer
160 Gate electrode
161 First gate electrode
162 Second gate electrode
170 Insulating layer
171 First insulating layer
172 Second insulating layer
180 Intermediate layer

1. A semiconductor device comprising:
an SJ layer extending in a first direction in a plane and configured by alternately arraying a plurality of semiconductor regions of a first conductivity type and a plurality of semiconductor regions of a second conductivity type in a second direction orthogonal to the first direction;
a first drain layer of the first conductivity type electrically connected to the SJ layer on one end side in the first direction;
a channel layer of the second conductivity type provided on the SJ layer on the other end side in the first direction;
a first source layer of the first conductivity type provided on the channel layer; and
a first gate electrode provided on a side of the channel layer and the first source layer in the first direction with a first insulating layer interposed therebetween.

2. The semiconductor device according to claim 1, wherein the first insulating layer is provided on the SJ layer with the first gate electrode embedded therein.

3. The semiconductor device according to claim 1, wherein the first gate electrode is provided between the channel layer and the first source layer, and the first drain layer.

4. The semiconductor device according to claim 3, wherein
the SJ layer is provided to extend in the first direction beyond the channel layer,
a second drain layer of the first conductivity type is further provided at an end portion of the SJ layer extending beyond the channel layer, and
the semiconductor device further comprises a second gate electrode provided through a second insulating layer on a side of the channel layer and the first source layer opposite to a side where the first gate electrode is provided.

5. The semiconductor device according to claim 4, wherein the first gate electrode and the second gate electrode are continuously provided so as to surround an entire periphery of the channel layer and the first source layer.

6. The semiconductor device according to claim 1, wherein the first gate electrode is provided on a side opposite to a side where the first drain layer is provided with respect to the channel layer and the first source layer.

7. The semiconductor device according to claim 6, wherein the channel layer is provided so as to surround an entire circumference of the first gate electrode.

8. The semiconductor device according to claim 7, wherein
the SJ layer is provided to extend in the first direction beyond the channel layer,
the semiconductor device further comprises a second drain layer of the first conductivity type at an end portion of the SJ layer extending beyond the channel layer, and
a second source layer is provided on the channel layer between the first gate electrode and the second drain layer.

9. The semiconductor device according to claim 1, further comprising an intermediate layer of the first conductivity type provided between the channel layer and the SJ layer.

10. The semiconductor device according to claim 1, wherein a depletion layer is formed in the semiconductor region of the first conductivity type of the SJ layer.

11. The semiconductor device according to claim 1, wherein the SJ layer is provided on an interlayer insulating layer including an insulating material.

12. The semiconductor device according to claim 11, wherein
the interlayer insulating layer is laminated with a semiconductor substrate, and
the SJ layer is provided on a laminated substrate including the interlayer insulating layer and the semiconductor substrate.

13. The semiconductor device according to claim 12, wherein the laminated substrate is provided with a pixel including a logic circuit or a photodiode.
